(19) United States
(12) Patent Application Publication
(10) Pub. No.: US 2016/0229687 A1
(43) Pub. Date: Aug. 11, 2016

(54) CHIP PACKAGE AND FABRICATION METHOD THEREOF

(71) Applicant: XINTEC INC., Taoyuan City (TW)

(72) Inventors: Ying-Nan WEN, Hsinchu City (TW); Ho-Yin YIU, Hsinchu City (TW); Chien-Hung LIU, New Taipei City (TW)

(21) Appl. No.: 15/008,371

(22) Filed: Jan. 27, 2016

Related U.S. Application Data
(60) Provisional application No. 62/113,998, filed on Feb. 9, 2015.

(51) Int. Cl. B81B 7/00; B81C 1/00

(52) U.S. Cl. CPC B81B 7/0041; B81C 1/00293; B81B 2207/11; B81C 2203/0109; B81C 2203/019

(57) ABSTRACT

A chip package included a chip, a first though hole, a laser stop structure, a first isolation layer, a second though hole and a conductive layer. The first though hole is extended from the second surface to the first surface of the chip to expose a conductive pad, and the laser stop structure is disposed on the conductive pad exposed by the first through hole, which an upper surface of the laser stop structure is above the second surface. The first isolation layer covers the second surface and the laser stop structure, and the first isolation layer has a third surface opposite to the second surface. The second though hole is extended from the third surface to the second surface to expose the laser stop structure, and a conductive layer is on the third surface and extended into the second though hole to contact the laser stop structure.

### RELATED APPLICATIONS

This application claims priority to U.S. provisional Application Ser. No. 62/113,998, filed Feb. 9, 2015, which is herein incorporated by reference.

### BACKGROUND

1. Field of Invention

The present invention relates to a chip package, especially a chip package having a micro-electromechanical device therein, and a fabrication method thereof.

2. Description of Related Art

Along with the trends of electronic devices toward lighter and more compact, the demand of functions of the electronic devices is correspondingly increased. In order to meet the needs of a variety of functions, semiconductor packages and electronic components having different functions are provided on a circuit board of the electronic device. However, since an amount of these elements is increased, a volume of the electronic device is bound to be increased, and thus resulting in the demand of miniaturization of the electronic devices could not be met. To satisfy the demand of miniaturization, the semiconductor packages are integrated with the electronic components to form a micro electro mechanical system (MEMS), which not only reduces the layout space of the circuit board to decrease the volume of the electronic device, but also maintains the needs of the variety of functions.

Generally, a micro-electromechanical device is formed in a chamber. However, various micro-electromechanical devices in a chip package respectively require environments having different pressures. For example, vacuum packaging technique provides a vacuum chamber for some micro-electromechanical devices, but some other micro-electromechanical devices should be placed in a non-vacuum chamber. Therefore, the difficulty of integrating different micro-electromechanical devices in one chip package is increased, and thus increases the cost of production and the processing time. Accordingly, a method of regulating the pressure of the chamber is necessary for the industry to increase the efficiency of the process.

### SUMMARY

The present disclosure provides a chip package including a substrate, a cap layer, a first chamber, a first micro-electromechanical device, a first plug and a first seal cap. The cap layer is disposed on the substrate, and the cap layer has a first opening penetrating the cap layer. The first chamber is disposed between the substrate and the cap layer, and the first micro-electromechanical device is disposed in the first chamber. The first plug disposed in the first opening, and the first seal cap is disposed above the cap layer to seal the first opening.

In various embodiments of the present disclosure, the first chamber is a non-vacuum environment.

In various embodiments of the present disclosure, an upper surface of the first plug and an upper surface of the cap layer are coplanar.

In various embodiments of the present disclosure, the first plug includes photosensitive epoxy.

In various embodiments of the present disclosure, the first seal cap completely covers an upper surface of the first plug.

In various embodiments of the present disclosure, the first seal cap includes an oxide, and the oxide is silicon dioxide.

In various embodiments of the present disclosure, the first seal cap includes a metal of aluminum.

Another aspect of the present disclosure provides a chip package including a substrate, a cap layer, a first chamber and a second chamber, a first micro-electromechanical device and a second micro-electromechanical device, a first plug and a first seal cap. The cap layer is disposed on the substrate, and the cap layer has a first opening penetrating the cap layer. The first chamber and the second chamber are disposed between the substrate and the cap layer; and the first micro-electromechanical device and the second micro-electromechanical device are respectively disposed in the first chamber and the second chamber. The first plug is disposed in the first opening, and the first seal cap is disposed above the cap layer to seal the first opening.

In various embodiments of the present disclosure, the first chamber is a non-vacuum environment, and the second chamber is a vacuum environment.

In various embodiments of the present disclosure, the first micro-electromechanical device is an acceleration sensor, and the second micro-electromechanical device is a gyroscope.

In various embodiments of the present disclosure, the cap layer further includes a second opening penetrating the cap layer.

In various embodiments of the present disclosure, the chip package further includes a second plug and a second seal cap. The second plug is disposed in the second opening, and the second seal cap is disposed above the cap layer to seal the second opening, which the first chamber is at a first pressure, and the second chamber is at a second pressure.

In various embodiments of the present disclosure, an upper surface of the first plug, an upper surface of the second plug and an upper surface of the cap layer are coplanar.

In various embodiments of the present disclosure, the first seal cap completely covers an upper surface of the first plug, and the second seal cap completely covers an upper surface of the second plug.

Another aspect of the present disclosure provides a method of fabricating a chip package, and the method includes following steps. A cap layer is bonded to a wafer to form a first chamber and a second chamber between the cap layer and the wafer, and a first micro-electromechanical device and a second micro-electromechanical device are respectively in the first chamber and the second chamber. A first opening is formed to penetrate the cap layer, and a first plug is formed in the first opening. A first seal cap is formed above the cap layer to seal the first opening.

In various embodiments of the present disclosure, the step of forming the first plug in the first opening includes following steps. A photosensitive epoxy is deposited to cover the cap layer, and a portion of the photosensitive epoxy is in the first opening. The photosensitive epoxy is patterned, and the photosensitive epoxy is polished to an upper surface of the cap layer to form the first plug in the first opening.

In various embodiments of the present disclosure, the step of forming the first seal cap above the cap layer to seal the first opening includes following steps. A sealing layer is formed to cover the cap layer and the first plug, and the sealing layer is patterned.

In various embodiments of the present disclosure, a pressure of the first chamber is adjusted to a first pressure after forming the first opening penetrating the cap layer.

In various embodiments of the present disclosure, the method of fabricating a chip package further includes following steps. A second opening is formed to penetrate the cap layer, and a pressure of the second chamber is adjusted to a second pressure. A second plug is formed in the second opening, and a second seal cap is formed above the cap layer to seal the second opening.

In various embodiments of the present disclosure, the method of fabricating a chip package further includes dicing the wafer along a scribe line to form the chip package.

### BRIEF DESCRIPTION OF THE DRAWINGS

The invention can be more fully understood by reading the following detailed description of the embodiment, with reference made to the accompanying drawings as follows:

FIG. 1 illustrates a cross-sectional view of a chip package according to various embodiments of the present disclosure.

FIGS. 2A and 2B illustrate top views of the chip package in FIG. 1 according to various embodiments of the present disclosure.

FIG. 3 illustrates a cross-sectional view of a chip package according to some other embodiments of the present disclosure.

FIG. 4 illustrates a cross-sectional view of a chip package according to some other embodiments of the present disclosure.

FIG. 5 illustrates a flow chart of a method of fabricating the chip package, in accordance with various embodiments.

FIGS. 6A to 6F are cross-sectional views of the chip package in FIG. 3 at intermediate stages of fabrication, in accordance with various embodiments.

FIG. 7 illustrates a flow chart of a method of fabricating the chip package, in accordance with various embodiments.

FIGS. 8A to 8H are cross-sectional views of the chip package in FIG. 4 at intermediate stages of fabrication, in accordance with various embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

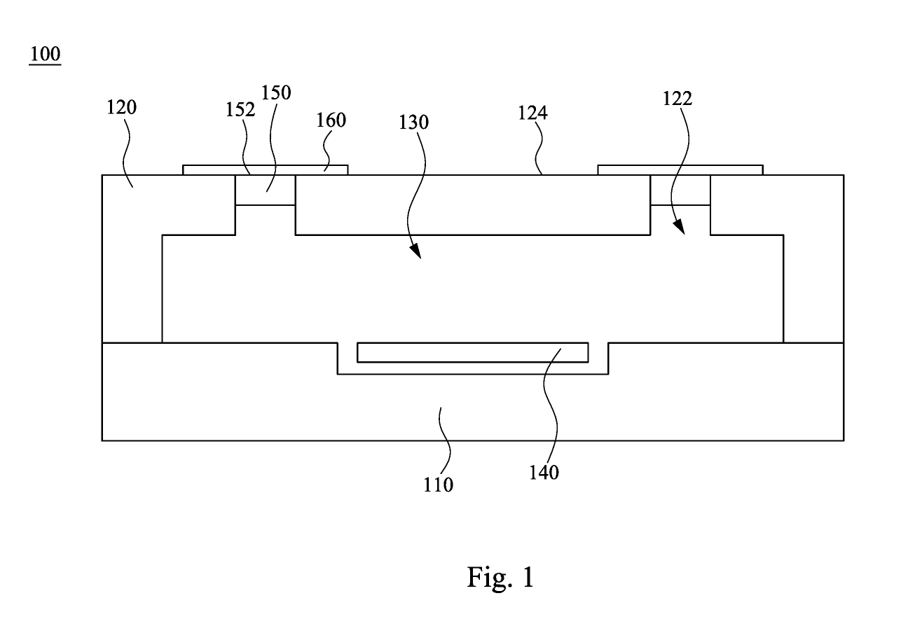

Refer to FIG. 1, which illustrates a cross-sectional view of a chip package according to various embodiments of the present disclosure. In FIG. 1, a chip package 100 includes a substrate 110, a cap layer 120, a first chamber 130, a first micro-electromechanical device 140, a first plug 150 and a first seal cap 160. The cap layer 120 is disposed on the substrate 110 to jointly form the first chamber 130 between the cap layer 120 and the substrate 110, and the first micro-electromechanical device 140 is in the first chamber 130.

In some embodiments, the substrate 110 is a chip structure of a complementary metal oxide semiconductor (CMOS), but not limited thereto. In some other embodiments, the substrate 110 is a ceramic circuit board or a metal board.

In some embodiments, the first micro-electromechanical device 140 includes physical sensors, RF circuits, accelerators, gyroscopes, micro actuators, surface acoustic wave (SAW) devices, pressure sensors, but not limited thereto.

In addition, the cap layer 120 further includes a first opening 122 penetrating the cap layer 120, and the first opening 122 is connected with the first chamber 130. It should be noticed that different types of micro-electromechanical devices respectively require different pressure environments. For example, the gyroscopes are very sensitive because of persistent vibration and should be disposed in a vacuum environment. On the other hand, the accelerators should be disposed in a non-vacuum environment to reduce noise generation. In response to the requirements of the different micro-electromechanical devices, a pressure of the first chamber 130 is adjusted through the first opening 122. In some embodiments, the first micro-electromechanical device 140 is an acceleration sensor, and gases are injected into the first chamber 130 through the first opening 122, so as to adjust a pressure of the first chamber 130 to 1 atmosphere (atm), but not limited thereto. In some other embodiments, the first micro-electromechanical device 140 is a gyroscope, and the first chamber 130 is evacuated to a vacuum through the first opening 122.

The first plug 150 is in the first opening 122, which a material of the first plug 150 includes photosensitive epoxy, and an upper surface 152 of the first plug 150 and an upper surface 124 of the cap layer 120 are coplanar. In addition, the first seal cap 160 is disposed above the cap layer 120 to seal the first opening 122, so as to prevent the gas leaking from the first plug 150. As such, the first chamber 130 is maintained at a pressure value required by the first micro-electromechanical device 140. In addition, the first seal cap 160 completely covers the upper surface 152 of the first plug 150. A material of the first seal cap 160 includes an oxide or a metal. For example, silicon dioxide is deposited by physical vapor depositing to form the first seal cap 160, or aluminum metal is deposited by sputtering to form the first seal cap 160, but not limited thereto. Any suitable oxides and metals could be used in the preparation of the first seal cap 160. Since the oxides and the metals are airtight materials, the first seal cap 160 could effectively prevent the gas leaking from the first plug 150, and thus enhances the yield of the chip package 100.

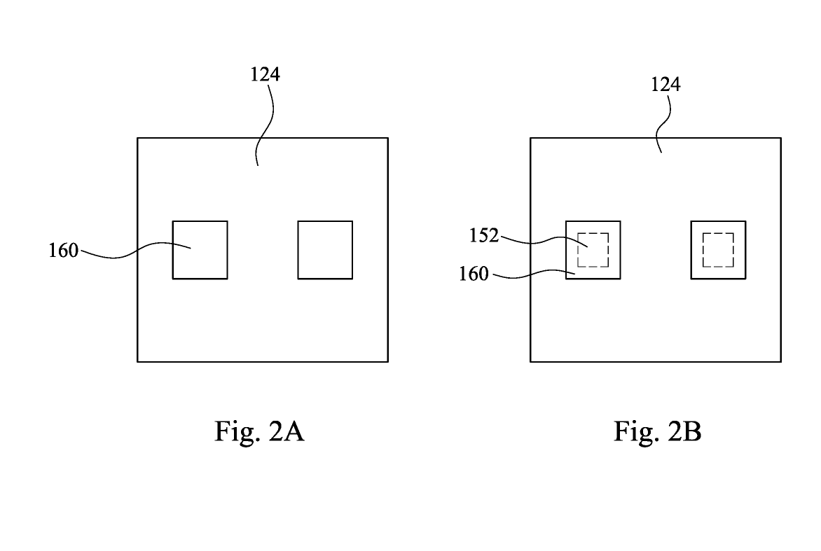

Continuing in FIGS. 2A and 2B, FIGS. 2A and 2B illustrate top views of the chip package in FIG. 1 according to various embodiments of the present disclosure. As shown in FIG. 2A, the first seal cap 160 is formed of the metal. Since the metal is an opaque material, only the first seal cap 160 above the upper surface 124 of the cap layer 120 is visible. On the other hand, the first seal cap 160 is formed of the oxide in FIG. 2B. Since the oxide is a transparent material, the upper surface 152 of the first plug 150 covered by the first seal cap 160 is also visible via the transparent first seal cap 160, which is above the upper surface 124 of the cap layer 120 to prevent gas leakage of the first chamber 130.

Following description relates to a chip package according some other embodiments, and it should be understood the materials of the elements mentioned above are not repeated herein.

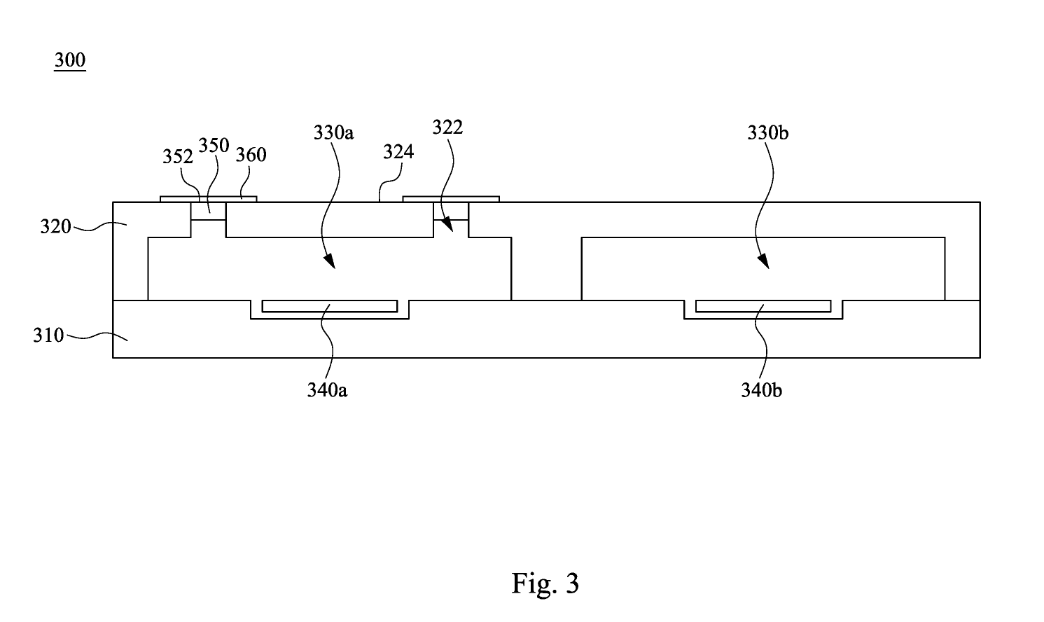

Continuing in FIG. 3, which illustrates a cross-sectional view of a chip package according to some other embodiments of the present disclosure. In FIG. 3, a chip package 300 includes a substrate 310, a cap layer 320, a first chamber 330a, a second chamber 330b, a first micro-electromechanical device 340a, a second micro-electromechanical device 340b, a first plug 350 and a first seal cap 360. The cap layer 320 is disposed on the substrate 310 to jointly form the first chamber 330a and the second chamber 330b between the cap layer 320 and the substrate 310, and the first micro-electromechanical device 340a and the second micro-electromechanical device 340b are respectively in the first chamber 330a and the second chamber 330b.

In present embodiments, the first micro-electromechanical device 340a is an acceleration sensor, and the second micro-electromechanical device 340b is a gyroscope. In the beginning of the process, the first chamber 330a and the second chamber 330b are both vacuum environments. On the purpose to adjust the first chamber 330a to a non-vacuum environment, the cap layer 320 has a first opening 322 penetrating the cap layer 320, and the first opening 322 is connected with the first chamber 330a for regulating a pressure of the first chamber 330a. As such, it is benefit for integrating the accelerator and the gyroscope in the same chip package.

The first plug 350 is in the first opening 322, and an upper surface 352 of the first plug 350 and an upper surface 324 of the cap layer 320 are coplanar. In addition, the first seal cap 360 is disposed above the cap layer 320 to seal the first opening 322, so as to prevent the gas leaking from the first plug 350. As such, the first chamber 330a is maintained at a pressure value required by the first micro-electromechanical device 340a (the acceleration sensor). Furthermore, the first seal cap 360 completely covers the upper surface 352 of the first plug 350 to effectively prevent the gas leaking from the first plug 350, and thus enhances the yield of the chip package 300.

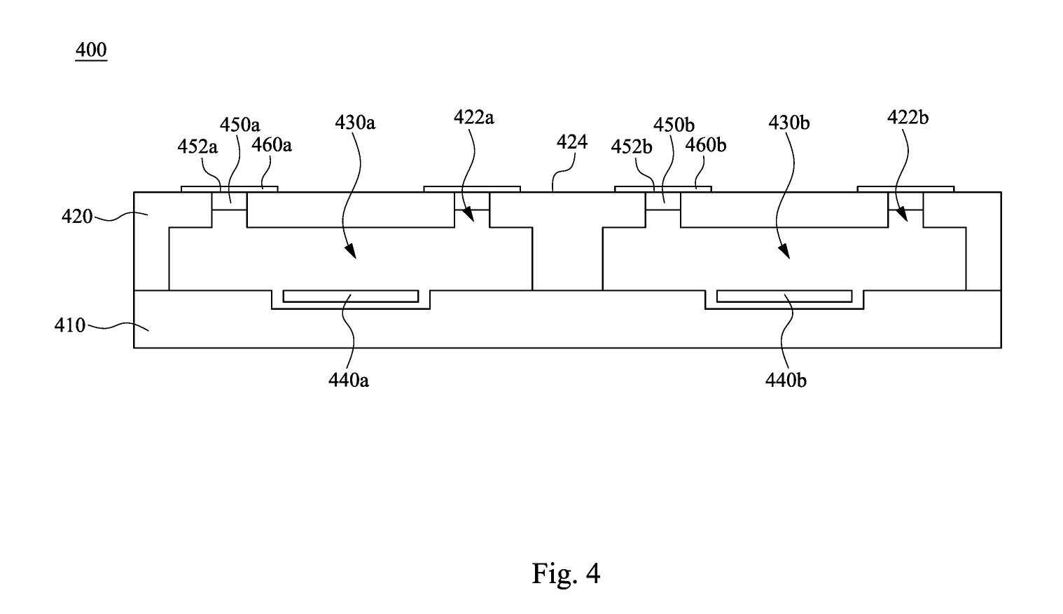

Continuing in FIG. 4, which illustrates a cross-sectional view of a chip package according to some other embodiments of the present disclosure. In FIG. 4, a chip package 400 includes a substrate 410, a cap layer 420, a first chamber 430a, a second chamber 430b, a first micro-electromechanical device 440a, a second micro-electromechanical device 440b, a first plug 450a, a second plug 450b, a first seal cap 460a and a second seal cap 460b. The cap layer 420 is disposed on the substrate 410 to jointly form the first chamber 430a and the second chamber 430b between the cap layer 420 and the substrate 410, and the first micro-electromechanical device 440a and the second micro-electromechanical device 440b are respectively in the first chamber 430a and the second chamber 430b.

In the beginning of the process, the first chamber 430a and the second chamber 430b are both vacuum environments. In the present embodiments, a pressure of the first chamber 430a is adjusted to a first pressure, and a pressure of the second chamber 430b is adjusted to a second pressure. The cap layer 420 has a first opening 422a and a second opening 422b penetrating the cap layer 420, which the first opening 422a is connected with the first chamber 430a for adjusting the pressure of the first chamber 430a to the first pressure, and the second opening 422b is connected with the second chamber 430b for adjusting the pressure of the second chamber 430b to the second pressure. The first pressure is different from the second pressure, but not limited thereto. In some embodiments, the first pressure is the same as the second pressure.

The first plug 450a and the second plug 450b are respectively in the first opening 422a and the second opening 422b, and an upper surface 452a of the first plug 450a, an upper surface 452b of the second plug 450b and an upper surface 424 of the cap layer 420 are coplanar. In addition, the first seal cap 460a and the second seal cap 460b are disposed above the cap layer 420 to respectively seal the first opening 422a and the second opening 422b, so as to prevent the gas leaking from the first plug 450a and the second plug 450b. As such, the first chamber 430a is maintained at the first pressure, and the second chamber 430b is maintained at the second pressure. Furthermore, the first seal cap 460a completely covers the upper surface 452a of the first plug 450a, and the second seal cap 460b completely covers the upper surface 452b of the second plug 450b, so as to effectively prevent the gas leaking from the first plug 450a and the second plug 450b, and thus enhances the yield of the chip package 400.

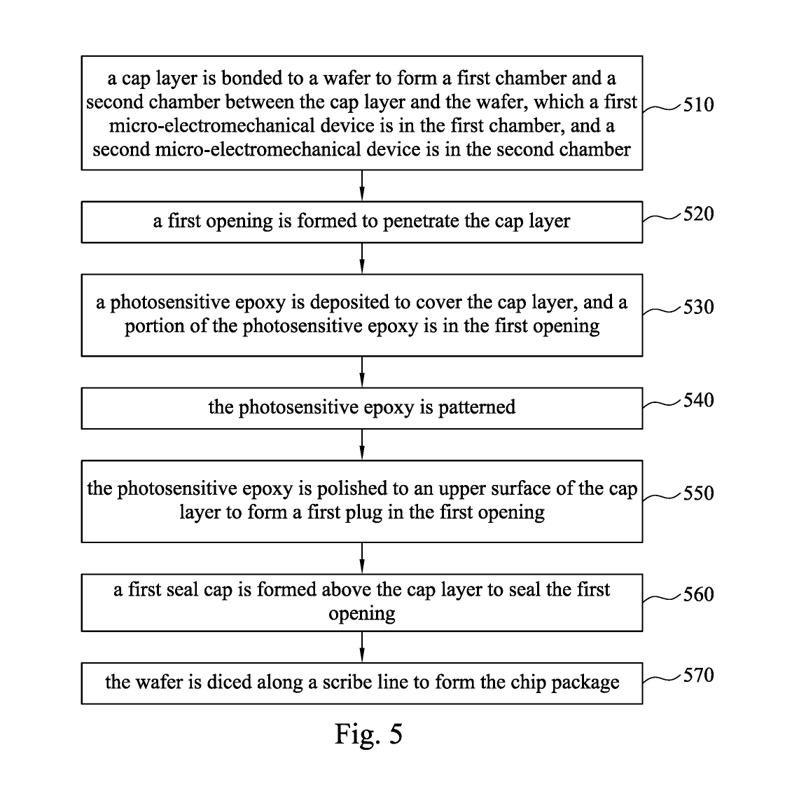

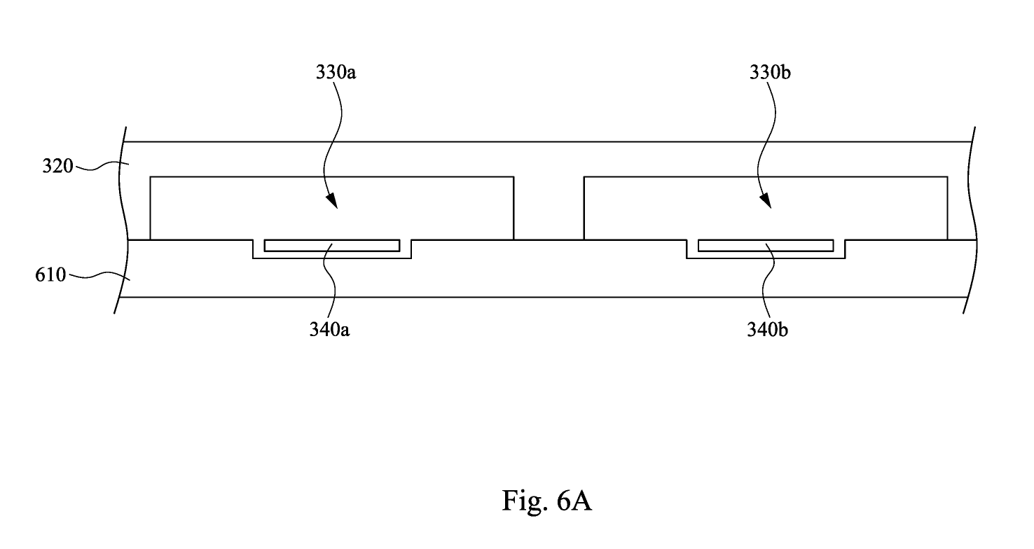

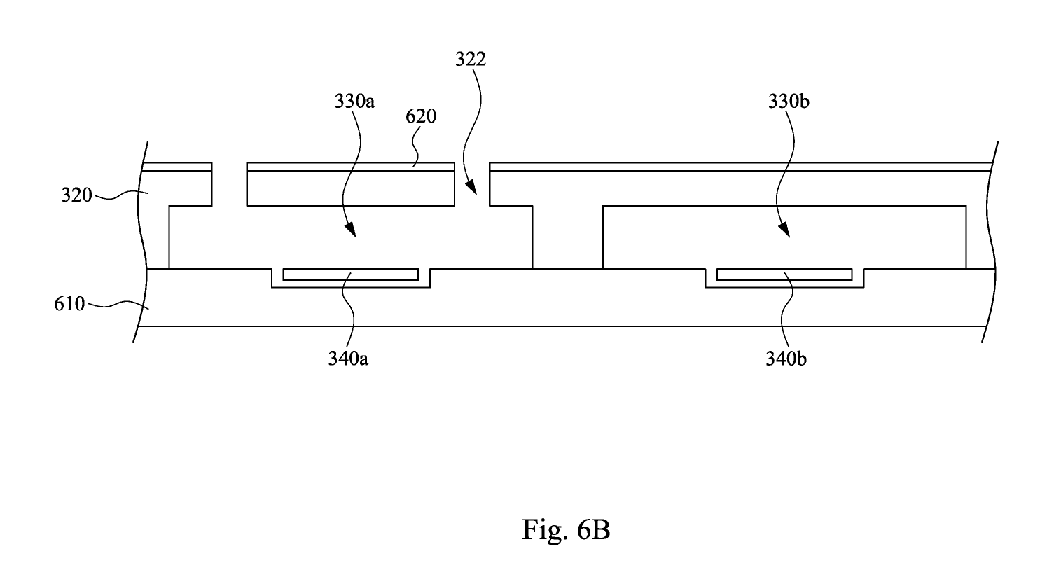

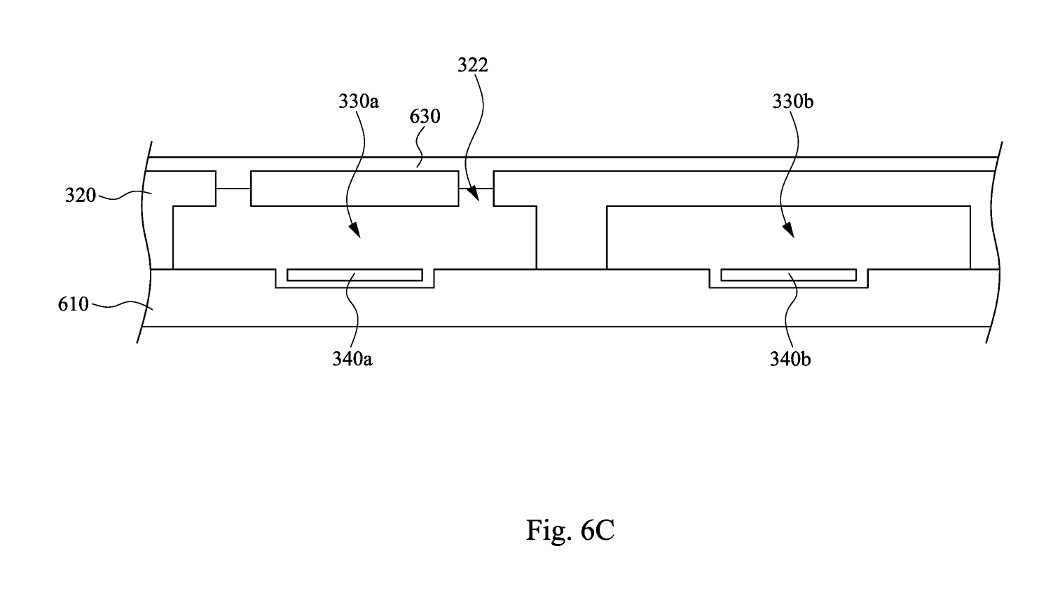

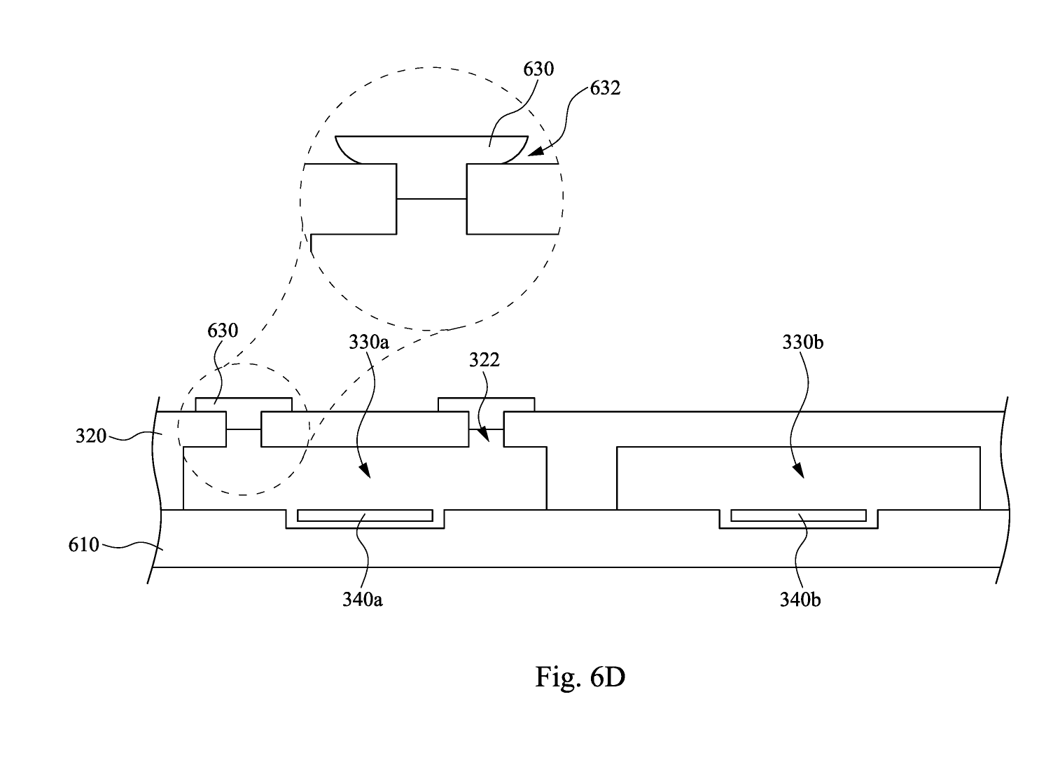

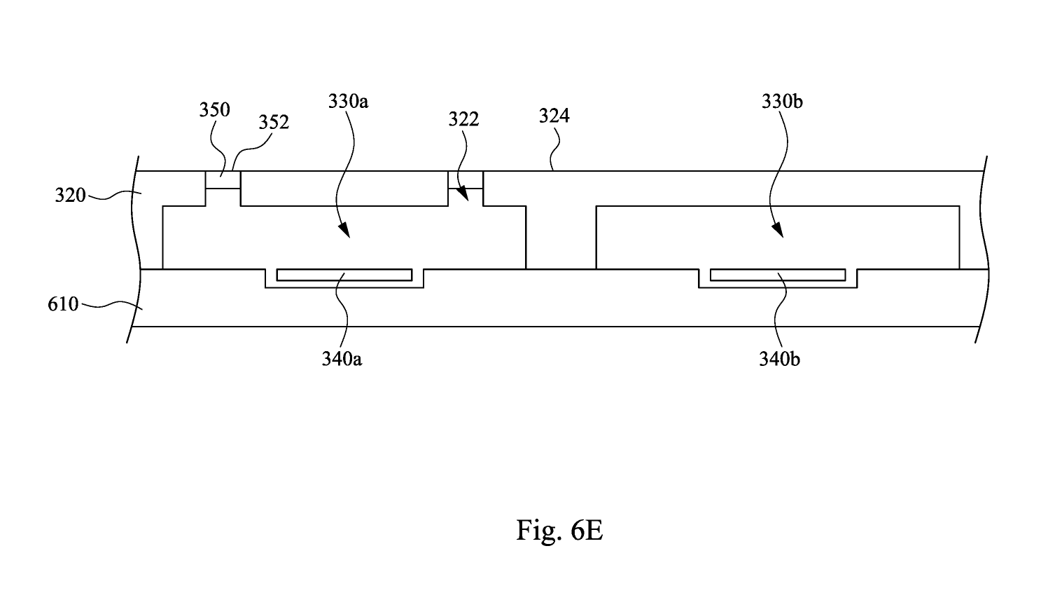

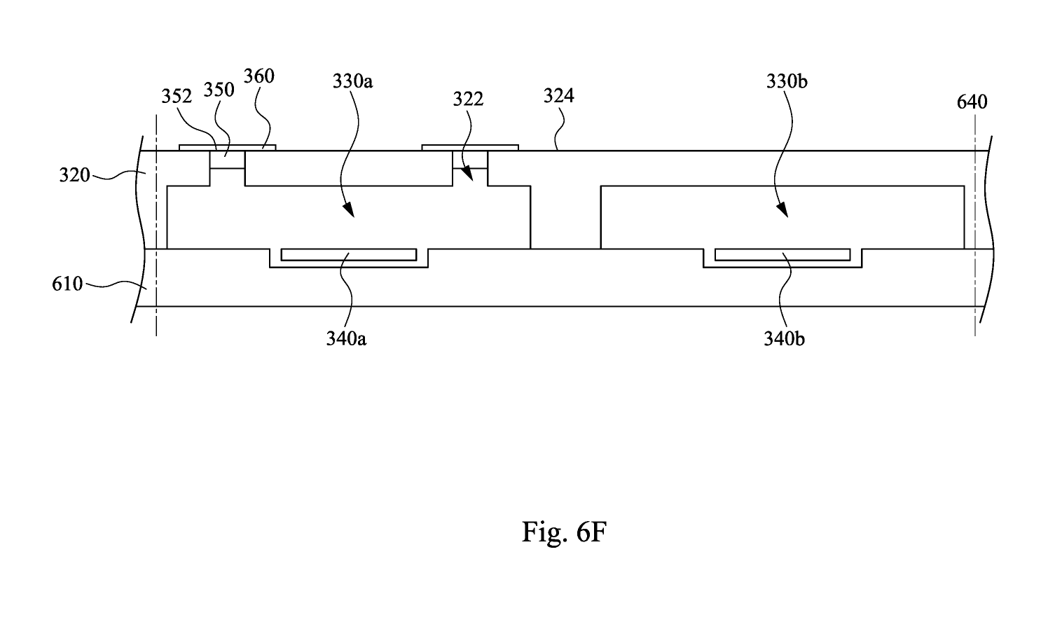

Refer to following descriptions to further understand a fabricating method of the chip package. Refer to FIG. 5 and FIGS. 6A to 6F at the same time to understand a fabricating method of the chip package in FIG. 3. FIG. 5 illustrates a flow chart of a method of fabricating the chip package, in accordance with various embodiments, and FIGS. 6A to 6F are cross-sectional views of the chip package in FIG. 3 at intermediate stages of fabrication, in accordance with various embodiments.

Refer to step 510 and FIG. 6A, a cap layer 320 is bonded to a wafer 610 to form a first chamber 330a and a second chamber 330b between the cap layer 320 and the wafer 610, which a first micro-electromechanical device 340a is in the first chamber 330a, and a second micro-electromechanical device 340b is in the second chamber 330b. In the following description, the wafer 610 is a semiconductor structure, which means that a plurality of substrates 310 shown in FIG. 3 are formed by dicing the wafer 610. It is worth noting that, the step of bonding the cap layer 320 and the wafer 610 is performed in a vacuum environment, so the first chamber 330a and the second chamber 330b are both vacuum environments.

Continuing in step 520 and FIG. 6B, a first opening 322 is formed to penetrate the cap layer 320. First, a photoresist layer 620 is formed on the cap layer 320, and a portion of the cap layer 320 is removed by photolithography etching to form the first opening 322 penetrating the cap layer 320. Then, the photoresist layer 620 is removed. Since the first opening 322 is connected with the first chamber 330a, a pressure of the first chamber 330a is adjusted to a first pressure via the first opening 332 after forming the first opening 322 penetrating the cap layer 320. As such, the first chamber 330a is no longer the vacuum environment.

In some other embodiments, the first opening 322 is first formed to penetrate the cap layer 320. After that, the cap layer 320 having the first opening 322 is bonded to the wafer 610.

Continuing in step 530 and FIG. 6C, a photosensitive epoxy 630 is deposited to cover the cap layer 320, and a portion of the photosensitive epoxy 630 is in the first opening 322. In this step, the photosensitive epoxy 630 is brush-coated on the cap layer 320, and the portion of the photosensitive epoxy 630 flows into the first opening 322.

Continuing in step 540 and FIG. 6D, the photosensitive epoxy 630 is patterned. In this step, the photosensitive epoxy 630 is also patterned by photolithography etching, but a pattern of the photosensitive epoxy 630 is defined without using a photoresist layer. It is worth noting that the photosensitive epoxy 630 has a recess 632 after patterning, which is unfavorable for forming the first seal cap 360 in the subsequent process. For example, when sputtering the metal or depositing the oxide, a discontinuous structure is easily formed, and the details are described thereafter.

Continuing in step 550 and FIG. 6E, the photosensitive epoxy 630 is polished to an upper surface 324 of the cap layer 320 to form a first plug 350 in the first opening 322. In this step, a mechanical polishing method is performed to remove the photosensitive epoxy 630 above the upper surface 324 of the cap layer 320, so as to form the first plug 350 having a flat upper surface 352. As such, it is benefit for forming the first seal cap 360 in the subsequent process.

In some embodiments, the step of patterning the photosensitive epoxy 630 is omitted. Instead, the photosensitive epoxy 630 is directly polished to the upper surface 324 of the cap layer 320, so as to form the first plug 350 in the first opening 322.

Continuing in step 560 and FIG. 6F, a first seal cap 360 is formed above the cap layer 320 to seal the first opening 322. In this step, a seal layer made of an oxide is formed on the cap layer 320 by physical vapor depositing, and the seal layer is patterned to form the first seal cap 360 covering the first plug 350, so as to seal the first opening 322. In other embodiments, a seal layer made of a metal is formed on the cap layer 320 by sputtering, and the seal layer is patterned to form the first seal cap 360 covering the first plug 350, so as to seal the first opening 322. Since the first plug 350 has the flat upper surface 352, it is benefit for forming the continuous first seal cap 360.

Continuing in step 570 and FIG. 6F, the wafer 610 is diced along a scribe line 640 to form the chip package 300. After forming the first seal cap 360, the wafer is diced along the scribe line 640, so as to form the chip package 300 shown in FIG. 3.

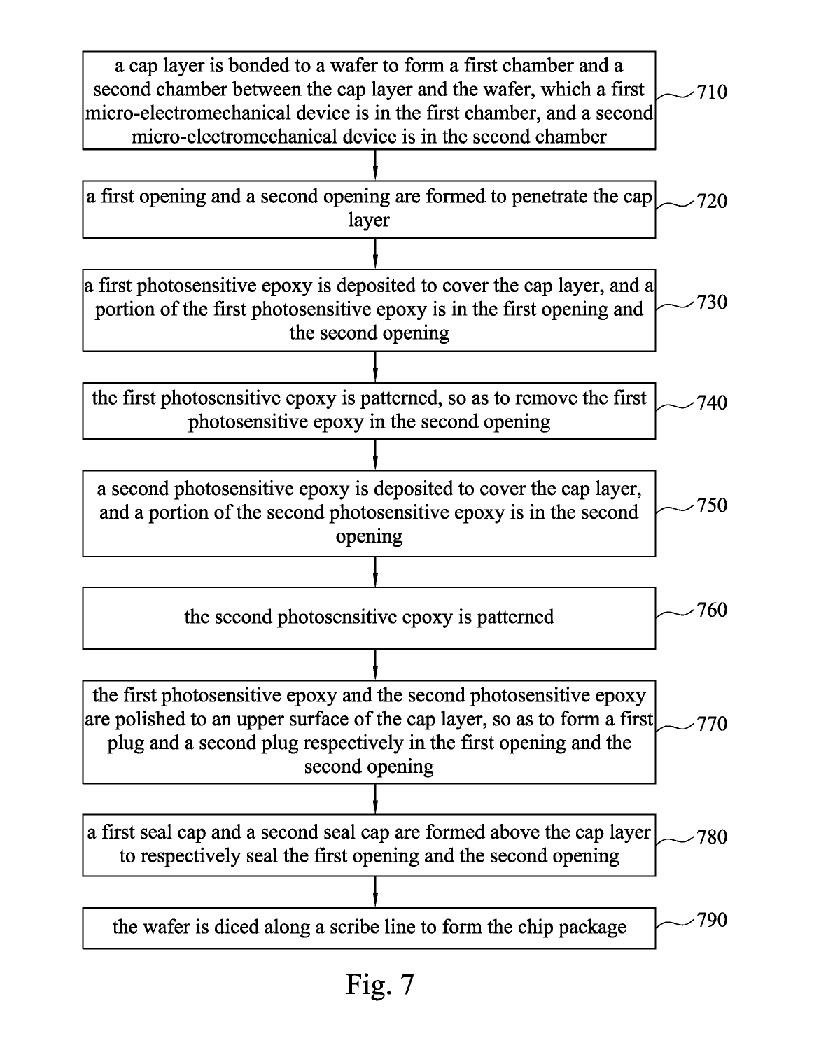

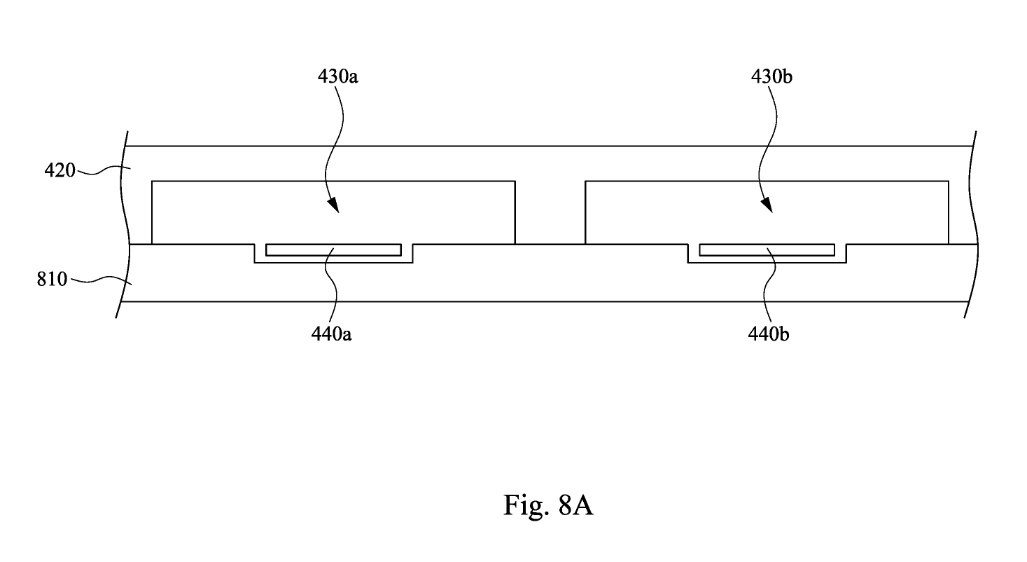

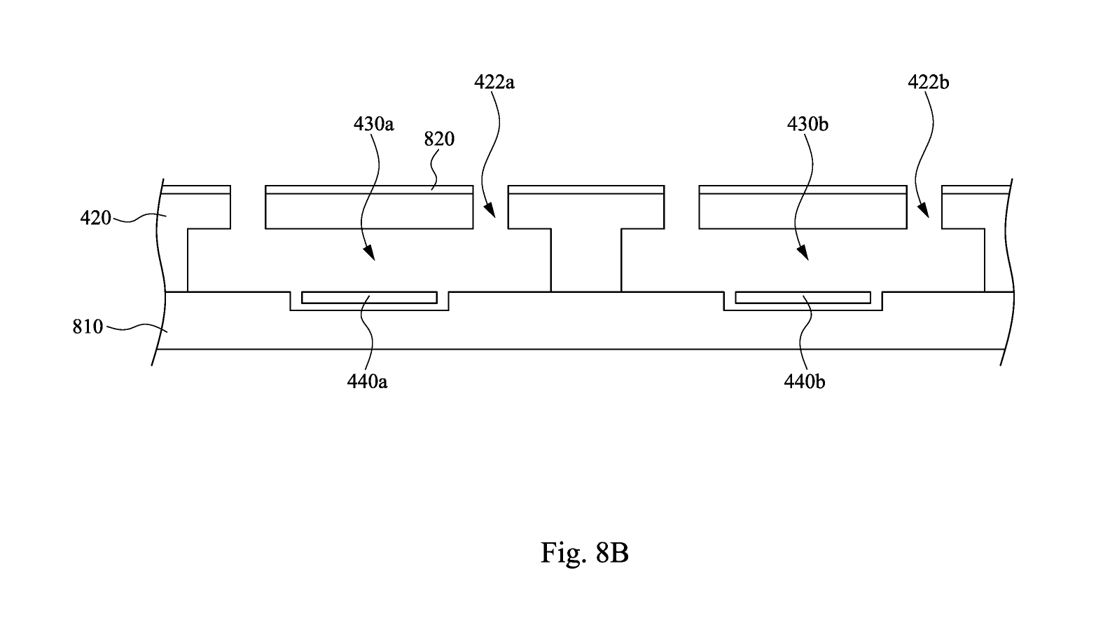

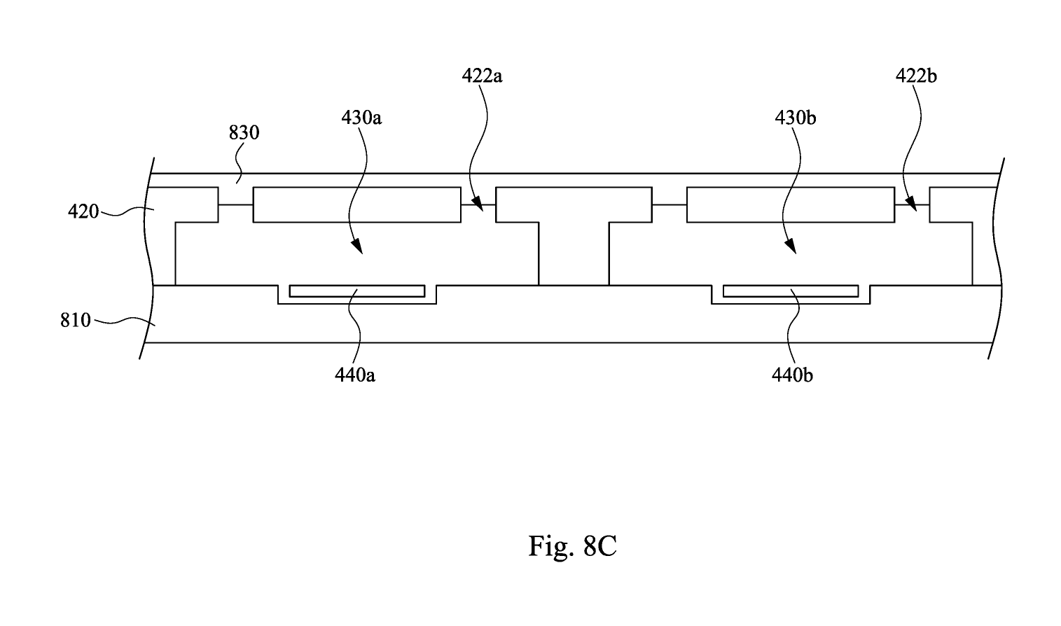

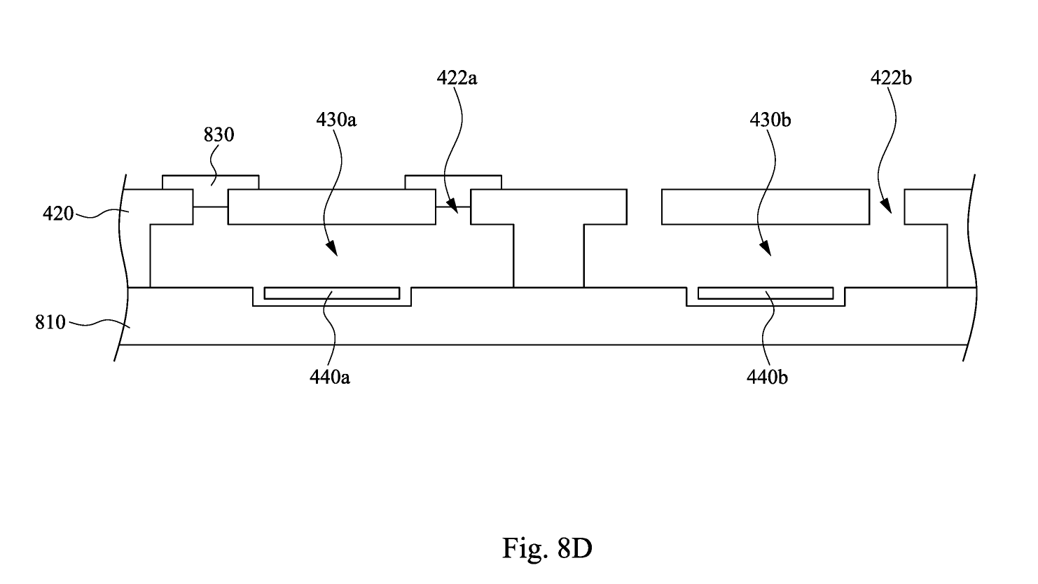

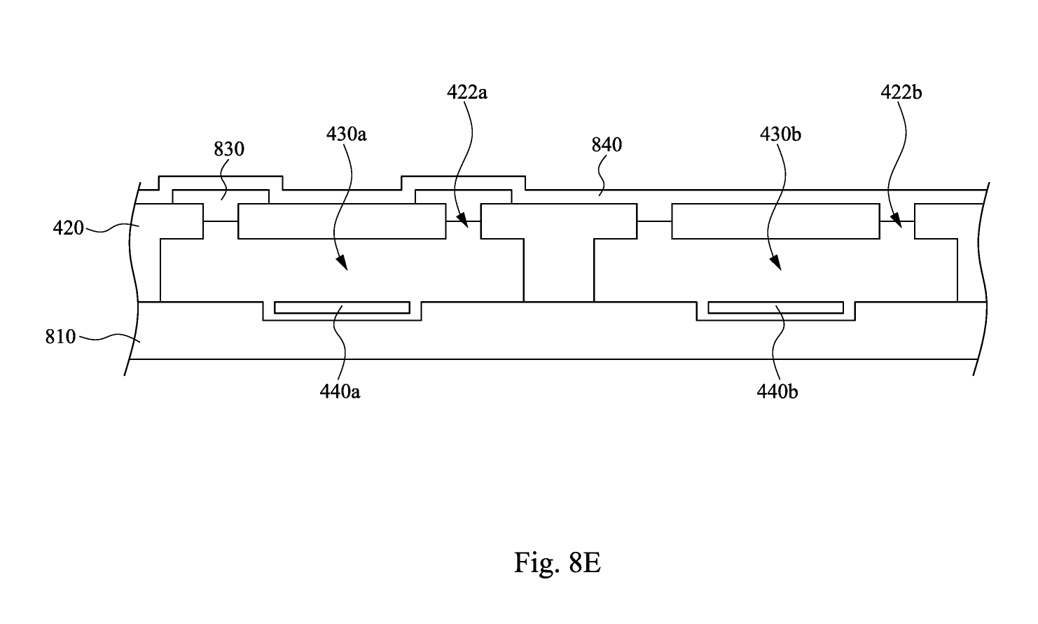

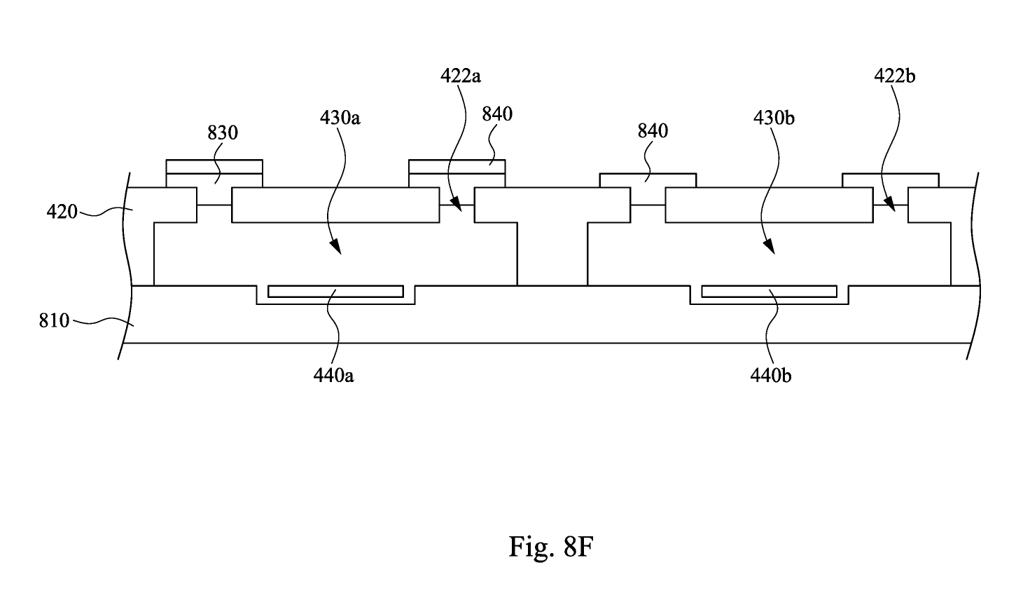

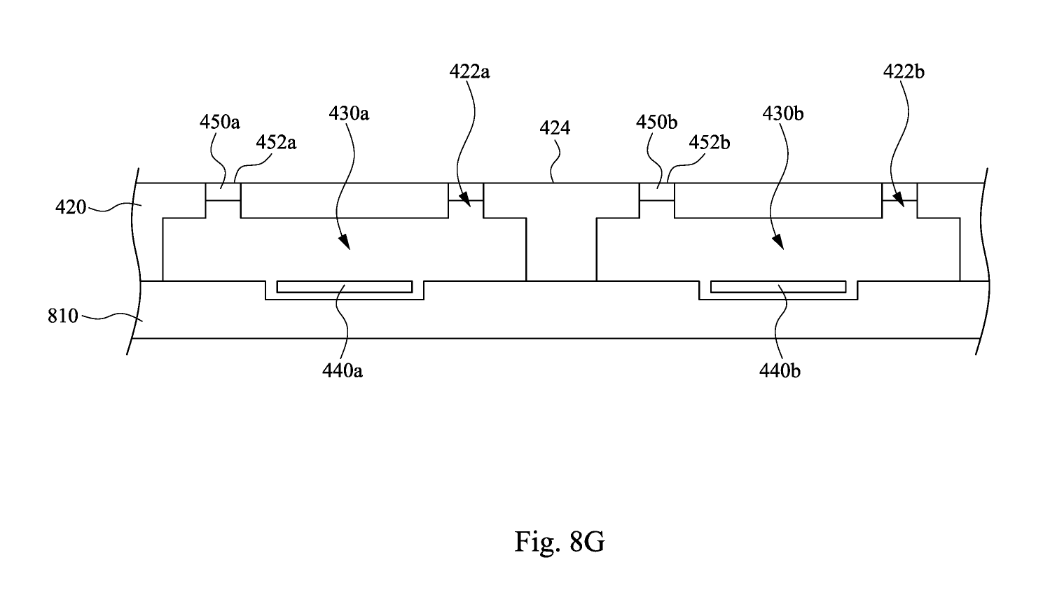

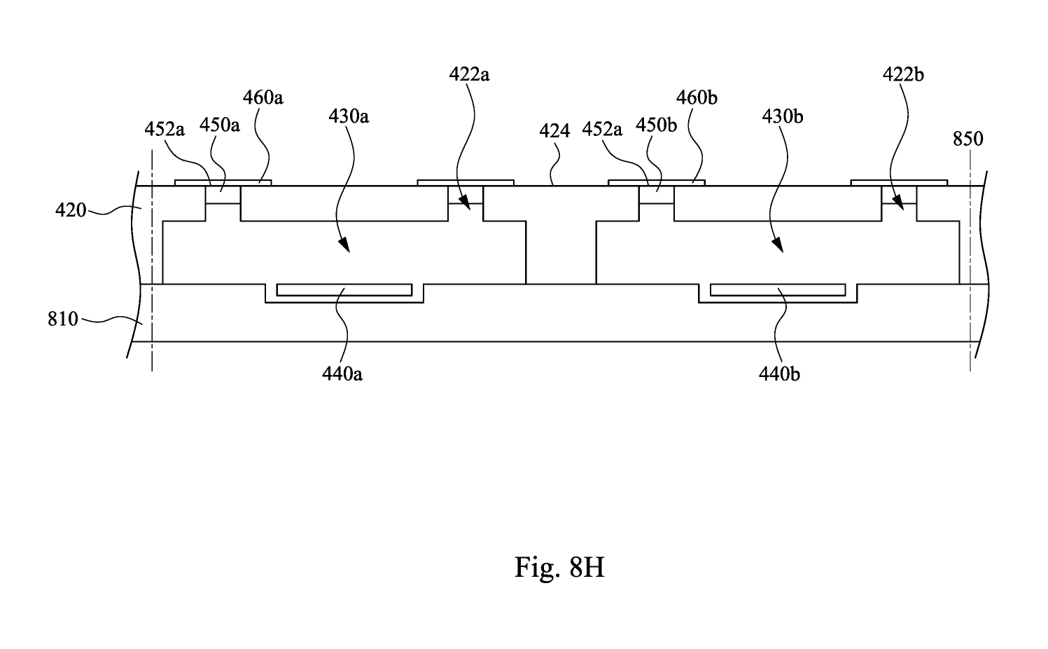

Refer to following descriptions to further understand another fabricating method of the chip package. Refer to FIG. 7 and FIGS. 8A to 8H at the same time to understand a fabricating method of the chip package in FIG. 4. FIG. 7 illustrates a flow chart of a method of fabricating the chip package, in accordance with various embodiments, and FIGS. 8A to 8H are cross-sectional views of the chip package in FIG. 4 at intermediate stages of fabrication, in accordance with various embodiments.

Refer to step 710 and FIG. 8A, a cap layer 420 is bonded to a wafer 810 to form a first chamber 430a and a second chamber 430b between the cap layer 420 and the wafer 810, which a first micro-electromechanical device 440a is in the first chamber 430a, and a second micro-electromechanical device 440b is in the second chamber 430b. In the following description, the wafer 810 is a semiconductor structure, which means that a plurality of substrates 410 shown in FIG. 4 are formed by dicing the wafer 810. It is worth noting that, the step of bonding the cap layer 420 and the wafer 810 is performed in a vacuum environment, so the first chamber 330a and the second chamber 330b are both vacuum environments.

Continuing in step 720 and FIG. 8B, a first opening 422a and a second opening 422b are formed to penetrate the cap layer 420. First, a photoresist layer 820 is formed on the cap layer 420, and a portion of the cap layer 420 is removed by photolithography etching to form the first opening 422a and the second opening 422b penetrating the cap layer 420. Then, the photoresist layer 820 is removed. The first opening 422a and the second opening 422b are respectively connected with the first chamber 430a and the second chamber 430b, so pressures of the first chamber 430a and the second chamber 430b are both adjusted to a first pressure via the first opening 422a and the second opening 422b after forming the first opening 422a and the second opening 422b penetrating the cap layer 420. As such, the first chamber 430a and the second chamber 430b are no longer the vacuum environments.

In some other embodiments, the first opening 422a and the second opening 422b are first formed to penetrate the cap layer 420. After that, the cap layer 420 having the first opening 422a and the second opening 422b is bonded to the wafer 810.

Continuing in step 730 and FIG. 8C, a first photosensitive epoxy 830 is deposited to cover the cap layer 420, and a portion of the first photosensitive epoxy 830 is in the first opening 422a and the second opening 422b. In this step, the first photosensitive epoxy 830 is brush-coated on the cap layer 420, and the portion of the first photosensitive epoxy 830 flows into the first opening 422a and the second opening 422b.

Continuing in step 740 and FIG. 8D, the first photosensitive epoxy 830 is patterned, so as to remove the first photosensitive epoxy 830 in the second opening 422b. In this step, the first photosensitive epoxy 830 is also patterned by photolithography etching, but a pattern of the photosensitive epoxy 830 is defined without using a photoresist layer. In this step, the first photosensitive epoxy 830 in the second opening 422b is removed, so the second opening 422b is again connected with the second chamber 430b. However, the first photosensitive epoxy 830 is remained in the first opening 430a. As aforementioned, the first chamber 430a and the second chamber 430b both have the first pressure, which the first chamber 430a is sealed by the first photosensitive epoxy 830 to maintain the first chamber 430a at the first pressure, and the second opening 422b connected with the second chamber 430b is for adjusting the second chamber 430b to a second pressure, which is different from the first pressure, but not limited thereto. In some embodiments, the first pressure is equal to the second pressure.

Continuing in step 750 and FIG. 8E, a second photosensitive epoxy 840 is deposited to cover the cap layer 420, and a portion of the second photosensitive epoxy 840 is in the second opening 422b. In this step, the second photosensitive epoxy 840 is brush-coated on the cap layer 420, so as to cover the cap layer 420 and the patterned first photosensitive epoxy 830. In addition, a portion of the second photosensitive epoxy 840 flows into the second opening 422b. The second photosensitive epoxy 840 in the second opening 422b is able to seal the second chamber 430b to maintain the second chamber 430b at the second pressure.

Continuing in step 760 and FIG. 8F, the second photosensitive epoxy 840 is patterned. In this step, the second photosensitive epoxy 840 is also patterned by photolithography etching, and a pattern of the second photosensitive epoxy 840 could be defined without using a photoresist layer. After the patterning process, the photosensitive epoxy 840 has one portion in the second opening 422b and the other portion above the first photosensitive epoxy 830.

Continuing in step 770 and FIG. 8G, the first photosensitive epoxy 830 and the second photosensitive epoxy 840 are polished to an upper surface 424 of the cap layer 420, so as to form a first plug 450a and a second plug 450b respectively in the first opening 422a and the second opening 422b. As the same reason mentioned in FIG. 7D, the patterning process will remain recesses on the first photosensitive epoxy 830 and the second photosensitive epoxy 840, and these recesses are unfavorable for forming the first seal cap 460a and the second seal cap 460b in the subsequent process. Accordingly, a mechanical polishing process is performed to remove the first photosensitive epoxy 830 and the second photosensitive epoxy 840 above the upper surface 424 of the cap layer 420. Therefore, the first plug 450a having a flat upper surface 452a and the second plug 450b having a flat upper surface 452b are formed, which is benefit for forming the first seal cap 460a and the second seal cap 460b in the subsequent process.

In some embodiments, the step of patterning the second photosensitive epoxy 840 is omitted. Instead, the first photosensitive epoxy 830 and the second photosensitive epoxy 840 are directly polished to the upper surface 424 of the cap layer 420, so as to form the first plug 450a and the second plug 450b respectively in the first opening 422a and the second opening 422b.

Continuing in step 780 and FIG. 8H, a first seal cap 460a and a second seal cap 460b are formed above the cap layer 420 to respectively seal the first opening 422a and the second opening 422b. In this step, a seal layer made of an oxide is formed above the cap layer 420 by physical vapor depositing, and the seal layer is patterned to form the first seal cap 460a and the second seal cap 460b respectively covering the first plug 450a and the second plug 450b, so as to seal the first opening 422a and the second opening 422b. In other embodiments, a seal layer made of a metal is formed above the cap layer 420 by sputtering, and the seal layer is patterned to form the first seal cap 460a and the second seal cap 460b respectively covering the first plug 450a and the second plug 450b, so as to seal the first opening 422a and the second opening 422b. Since the first plug 450a and the second plug 450b respectively have the flat upper surfaces 452a and 452b, it is benefit for forming the continuous first seal cap 460a and the second seal cap 460b.

Continuing in step 790 and FIG. 8H, the wafer 810 is diced along a scribe line 850 to form the chip package 400. After forming the first seal cap 460a and the second seal cap 460b, the wafer 810 is diced along the scribe line 850, so as to form the chip package 400 shown in FIG. 4.

The embodiments of the present disclosure discussed above have advantages over existing methods and structures, and the advantages are summarized below. The present disclosure uses a wafer-level packaging technology to prepare environments having various pressures required by different micro-electromechanical devices, so as to integrate these micro-electromechanical devices in one chip package. In addition, the seal cap made of the metal or the oxide further prevents the gas leakage of the chamber, and thus increases the yield and the lifetime of the chip package. Accordingly, a novel and simple process of regulating the pressure of the chamber is provided by the present disclosure, so as to increase the efficiency of the process.

Although the present invention has been described in considerable detail with reference to certain embodiments thereof, other embodiments are possible. Therefore, the spirit and scope of the appended claims should not be limited to the description of the embodiments contained herein. Reference will now be made in detail to the embodiments of the invention, examples of which are illustrated in the accompanying drawings. Wherever possible, the same reference numbers are used in the drawings and the description to refer to the same or like parts.

What is claimed is:

1. A chip package, comprising:
a substrate;
a cap layer disposed on the substrate, and the cap layer having a first opening penetrating the cap layer;
a first chamber disposed between the substrate and the cap layer;
a first micro-electromechanical device disposed in the first chamber;
a first plug disposed in the first opening; and
a first seal cap disposed above the cap layer to seal the first opening.

2. The chip package of claim 1, wherein the first chamber is a non-vacuum environment.

3. The chip package of claim 1, wherein an upper surface of the first plug and an upper surface of the cap layer are coplanar.

4. The chip package of claim 1, wherein the first plug comprises photosensitive epoxy.

5. The chip package of claim 1, wherein the first seal cap completely covers an upper surface of the first plug.

6. The chip package of claim 1, wherein the first seal cap comprises an oxide, and the oxide is silicon dioxide.

7. The chip package of claim 1, wherein the first seal cap comprises a metal of aluminum.

8. A chip package, comprising:
a substrate;
a cap layer disposed on the substrate, and the cap layer having a first opening penetrating the cap layer;
a first chamber and a second chamber disposed between the substrate and the cap layer;
a first micro-electromechanical device disposed in the first chamber;
a second micro-electromechanical device disposed in the second chamber;
a first plug disposed in the first opening; and
a first seal cap disposed above the cap layer to seal the first opening.

9. The chip package of claim 8, wherein the first chamber is a non-vacuum environment, and the second chamber is a vacuum environment.

10. The chip package of claim 9, wherein the first micro-electromechanical device is an acceleration sensor, and the second micro-electromechanical device is a gyroscope.

11. The chip package of claim 8, wherein the cap layer further comprises a second opening penetrating the cap layer.

12. The chip package of claim 11, further comprising:
a second plug disposed in the second opening; and
a second seal cap disposed above the cap layer to seal the second opening, wherein the first chamber is at a first pressure, and the second chamber is at a second pressure.

13. The chip package of claim 12, wherein an upper surface of the first plug, an upper surface of the second plug and an upper surface of the cap layer are coplanar.

14. The chip package of claim 12, wherein the first seal cap completely covers an upper surface of the first plug, and the second seal cap completely covers an upper surface of the second plug.

15. A method of fabricating a chip package, the method comprising:
bonding a cap layer to a wafer to form a first chamber and a second chamber between the cap layer and the wafer, a first micro-electromechanical device being in the first chamber, and a second micro-electromechanical device being in the second chamber;
forming a first opening penetrating the cap layer;
forming a first plug in the first opening; and
forming a first seal cap above the cap layer to seal the first opening.

16. The method of fabricating the chip package of claim 15, wherein forming the first plug in the first opening comprises:
depositing a photosensitive epoxy to cover the cap layer, and a portion of the photosensitive epoxy being in the first opening;
patterning the photosensitive epoxy; and
polishing the photosensitive epoxy to an upper surface of the cap layer to form the first plug in the first opening.

17. The method of fabricating the chip package of claim 16, wherein forming the first seal cap above the cap layer to seal the first opening comprises:
forming a sealing layer to cover the cap layer and the first plug; and
patterning the sealing layer.

18. The method of fabricating the chip package of claim 15, further comprising:
adjusting a pressure of the first chamber to a first pressure after forming the first opening penetrating the cap layer.

19. The method of fabricating the chip package of claim 18, further comprising:
forming a second opening penetrating the cap layer;
adjusting a pressure of the second chamber to a second pressure
forming a second plug in the second opening; and
forming a second seal cap above the cap layer to seal the second opening.

20. The method of fabricating the chip package of claim 15, further comprising:
dicing the wafer along a scribe line to form the chip package.
